(19) United States
(12) Patent Application Publication
(10) Pub. No.: US 2023/0207271 A1
(43) Pub. Date: Jun. 29, 2023

(54) APPARATUS FOR TREATING SUBSTRATE

(71) Applicants: SEMES CO., LTD., Cheonan-si (KR); PUSAN NATIONAL UNIVERSITY INDUSTRY-UNIVERSITY COOPERATION FOUNDATION, Busan (KR)

(72) Inventors: Yoon Seok CHOI, Suwon-si (KR); Sun Wook JUNG, Hwaseong-si (KR); Jong Won PARK, Hwaseong-si (KR); Ho-Jun LEE, Busan (KR); Min Sang PARK, Busan (KR)

(73) Assignees: SEMES CO., LTD., Cheonan-si (KR); PUSAN NATIONAL UNIVERSITY INDUSTRY-UNIVERSITY COOPERATION FOUNDATION, Busan (KR)

(21) Appl. No.: 18/055,917

(22) Filed: Nov. 16, 2022

(30) Foreign Application Priority Data
Dec. 28, 2021 (KR) 10-2021-0190313

(51) Int. Cl. H01J 37/32

(52) U.S. Cl. CPC H01J 37/32201; H01J 37/3244; H01J 37/32229; H01J 2237/327

(57) ABSTRACT

The apparatus includes a process chamber having a treating space therein, a support unit for supporting the substrate in the treating space, a gas supply unit for supplying treating gas to the treating space, and a microwave application unit for applying microwaves to the treating gas to generate plasma. The microwave application unit may include first power supply for applying a first microwave, a support plate having a groove formed on an upper surface thereof and combined with the process chamber above the support unit to define the treating space, a first transmission plate inserted into the groove to radiate the first microwave to the treating space, and a first waveguide disposed to overlap with an upper portion of the first transmission plate and coupled to the first power supply, wherein a plurality of grooves may be formed along a circumferential direction in an edge region of the support plate.

### CROSS-REFERENCE TO RELATED APPLICATIONS

This application claims priority to and the benefit of the Korean Patent Application No. 10-2021-0190313 filed in the Korean Intellectual Property Office on Dec. 28, 2021, the entire contents of which are incorporated herein by reference.

### TECHNICAL FIELD

The present invention relates to an apparatus for treating a substrate, and more particularly, to an apparatus for treating a substrate of plasma-treating the substrate.

### BACKGROUND ART

Plasma refers to an ionized gas state composed of ions, radicals, and electrons. The plasma is generated by very high temperatures, strong electric fields, or RF electromagnetic fields. In a semiconductor device manufacturing process, various processes are performed using plasma.

FIG. 1 is a diagram schematically illustrating a general substrate treating apparatus for treating a substrate using a microwave. Referring to FIG. 1, a substrate W is supported in a treating space 1001 of a process chamber 1000, and a treating gas supplied into the treating space 1001 is excited using microwaves to generate plasma, so that the substrate W is treated. An antenna plate 1100 having a slot 1102 is provided in an upper region of the substrate W. A dielectric plate 1200 is disposed above the antenna plate 1100, and a transmission plate 1300 is disposed below the antenna plate 1100. When the microwave is applied to the antenna plate 1100, the microwaves are transmitted along a radial direction of the antenna plate 1100 and then transmitted to the treating space 1001 through the slot 1102 and the transmission plate 1300.

When the substrate treating apparatus having the structure illustrated in FIG. 1 is used, structural complexity of components disposed above the treating space 1001 is accompanied. There are many space restrictions on the upper region of the treating space 1001. In addition, the antenna plate 1100 has a thin thickness to smoothly transmit microwaves toward the transmission plate 1300. The microwaves transmitted to the antenna plate 1100 generate a current while passing through the slot 1102. Since the current is generated, the antenna plate 1100 is heated to cause thermal deformation in the upper structure. When a cooling structure is further installed to suppress heat generation, the structural complexity of the upper space is increased. When the heat generation is not suppressed, the antenna plate 1100 provided with a thin thickness may be deformed, so that the microwaves cannot be smoothly transmitted to the treating space 1001. Furthermore, the transmission plate 1300 is integrally formed with the antenna plate 1100 to be coupled to one side wall of the process chamber 1000. When the transmission plate 1300 is deformed by heat transmitted from the antenna plate 1100, maintenance cost increases. In addition, in order to replace the integrally formed transmission plate 1300, since the antenna plate 1100, the dielectric plate 1200, and the transmission plate 1300 of the substrate treating apparatus all need to be disassembled, replacement is not easy, and the time required for maintenance is increased.

In addition, when microwaves are transmitted to the treating space 1001 through the antenna plate 1100, there is a problem in that the microwaves are concentrated only in the central region of the treating space 1001. Accordingly, the density of microwaves is relatively weak in an edge region of the treating space 1001 compared to a central region thereof. For this reason, plasma treatment on the edge region of the substrate is not easily performed. In addition, due to the structure of the antenna plate 1100, the dielectric plate 1200, and the transmission plate 1300, the treating gas cannot be supplied from the upper portion of the treating space 1001. Accordingly, the treating gas is not smoothly supplied into the treating space 1001, thereby impairing the uniformity of plasma formed in the treating space 1001.

### SUMMARY OF THE INVENTION

The present invention has been made in an effort to provide an apparatus for treating a substrate capable of uniformly forming plasma in a treating space where the substrate is to be treated.

The present invention has also been made in an effort to provide an apparatus for treating a substrate capable of minimizing the structural complexity of the substrate treating apparatus.

The present invention has also been made in an effort to provide an apparatus for treating a substrate capable of minimizing the deformation of members due to heat generated in a process of transmitting microwaves.

The present invention has also been made in an effort to provide an apparatus for treating a substrate capable of efficiently replacing a transmission plate.

The problem to be solved by the present invention is not limited to the above-mentioned problems, and the problems not mentioned will be clearly understood by those skilled in the art from the present specification and the accompanying drawings.

An exemplary embodiment of the present invention provides an apparatus for treating a substrate. The apparatus for treating the substrate includes a process chamber having a treating space therein, a support unit for supporting the substrate in the treating space, a gas supply unit for supplying treating gas to the treating space, and a microwave application unit for applying microwaves to the treating gas to generate plasma, wherein the microwave application unit may include first power supply for applying a first microwave, a support plate having a groove formed on an upper surface thereof and combined with the process chamber above the support unit to define the treating space, a first transmission plate inserted into the groove to radiate the first microwave to the treating space, and a first waveguide disposed to overlap with an upper portion of the first transmission plate and coupled to the first power supply, wherein a plurality of grooves may be provided, and the plurality of grooves may be formed along a circumferential direction in an edge region of the support plate, when viewed from the top.

In the exemplary embodiment, a plurality of first transmission plates may be provided, and the plurality of first transmission plates may be combined with each other to have a ring shape, when viewed from the top.

In the exemplary embodiment, the first waveguide may be formed in a ring shape when viewed from the top.

In the exemplary embodiment, a plurality of first slots may be formed on a lower surface of the first waveguide, and the plurality of first slots may be spaced apart from each other along a circumferential direction of the first waveguide.

In the exemplary embodiment, the plurality of first slots may be disposed in a plurality of rows when viewing the first waveguide from a front cross section.

In the exemplary embodiment, the plurality of first slots may be provided to be opened and closed.

In the exemplary embodiment, on the upper surface of the support plate, a central groove formed in a region including the center of the support plate may be further formed, and the microwave application unit may further include a second power supply for applying a second microwave, a second transmission plate inserted into the central groove to radiate the second microwave to the treating space, and a second waveguide disposed above the second transmission plate and coupled to the second power supply, wherein at least one or more second slots may be formed on a lower surface of the second waveguide.

In the exemplary embodiment, the grooves may include a first groove formed in a part of the circumferential direction of the edge region of the support plate and second groove formed in the other part of the circumferential direction of the edge region of the support plate, wherein the first groove and the second groove may be combined with each other to form a ring shape.

In the exemplary embodiment, the first transmission plate may be inserted into the first groove, and the microwave application unit may include a third power supply for applying a third microwave, third transmission plate inserted into the second groove to radiate the third microwave to the treating space, and a third waveguide disposed above the third transmission plate and coupled to the third power supply, wherein a plurality of third slots may be formed on a lower surface of the third waveguide, and the plurality of third slots may be spaced apart from each other along a circumferential direction of the third waveguide.

In the exemplary embodiment, the substrate treating apparatus may further include a gas supply unit for supplying the treating gas to the treating space, wherein a gas channel through which the treating gas flows may be formed in the support plate.

In the exemplary embodiment, the support plate may be grounded.

In the exemplary embodiment, high-frequency power may be applied to the support plate.

Another exemplary embodiment of the present invention provides an apparatus for treating a substrate. The apparatus for treating the substrate includes a chamber having a treating space defined therein, a support unit for supporting the substrate in the treating space, and a microwave application unit for applying microwaves to treating gas supplied to the treating space to generate plasma, wherein the microwave application unit may include a first power supply for applying a first microwave, a support plate having a groove formed on an upper surface thereof and combined with the chamber above the support unit to define the treating space, a first transmission plate inserted into the groove to radiate the first microwave to the treating space, and a first waveguide disposed to overlap with the first transmission plate above the first transmission plate and coupled to the first power supply, wherein the first waveguide may be provided in a ring shape when viewed from the top.

In the exemplary embodiment, a plurality of first slots may be formed on a lower surface of the first waveguide, and the plurality of first slots may be spaced apart from each other along a circumferential direction of the first waveguide.

In the exemplary embodiment, the plurality of first slots may be disposed in a plurality of ring shapes.

In the exemplary embodiment, a plurality of grooves may be provided, and the plurality of grooves may be formed along a circumferential direction in an edge region of the support plate, when viewed from the top, wherein a plurality of first transmission plates may be provided, and the plurality of first transmission plates may be combined with each other to have a ring shape, when viewed from the top.

In the exemplary embodiment, on the upper surface of the support plate, a central groove formed in a region including the center of the support plate may be further formed, and the microwave application unit may further include a second power supply for applying a second microwave, a second transmission plate inserted into the central groove to radiate the second microwave to the treating space, and a second waveguide disposed above the second transmission plate and coupled to the second power supply, wherein at least one or more second slots may be formed on a lower surface of the second waveguide.

In the exemplary embodiment, the grooves may include a first groove formed in a part of the circumferential direction of the edge region of the support plate and inserted with the first transmission plate and a second groove formed in the other part of the circumferential direction of the edge region of the support plate, wherein the first groove and the second groove may be combined with each other to form a ring shape, and the microwave application unit may further include a third power supply for applying a third microwave, a third transmission plate inserted into the second groove to radiate the third microwave to the treating space, and a third waveguide disposed above the third transmission plate and coupled to the third power supply, wherein a plurality of third slots may be formed on a lower surface of the third waveguide, and the plurality of third slots may be spaced apart from each other along a circumferential direction of the third waveguide.

Yet another exemplary embodiment of the present invention provides an apparatus for treating a substrate. The apparatus for treating the substrate includes a process chamber having a treating space formed therein, a support unit for supporting the substrate in the treating space, a gas supply unit for supplying treating gas to the treating space, a first power supply for applying a first microwave, a second power supply for applying a second microwave, a support plate combined with the process chamber above the support unit to define the treating space, a first transmission plate disposed above the support plate to radiate the first microwave to the treating space, a second transmission plate disposed above the support plate to radiate the second microwave to the treating space, a first waveguide coupled to the first power supply and disposed on an upper surface of the first transmission plate, and having a plurality of first slots formed on a lower surface thereof, and a second waveguide coupled to the second power supply and disposed on an upper surface of the second transmission plate, and having at least one or more second slots formed on a lower surface thereof, wherein the upper surface of the support plate may have a central groove formed in a region including the center of the support plate, and a groove formed in a region facing an edge of the support plate surrounding the central groove, wherein the first transmission plate may be inserted into the groove, and the second transmission plate may be inserted into the central groove.

In the exemplary embodiment, a plurality of grooves may be provided, and the plurality of grooves may be formed along a circumferential direction of the support plate, when viewed from the top, wherein a plurality of first transmission plates may be provided, and the plurality of first transmission plates may be combined with each other to have a ring shape, when viewed from the top, wherein the first waveguide may be formed in a ring shape when viewed from the top.

According to the exemplary embodiment of the present invention, it is possible to uniformly form plasma in a treating space where a substrate is to be treated.

Further, according to the exemplary embodiment of the present invention, it is possible to minimize the structural complexity of the substrate treating apparatus.

Furthermore, according to the exemplary embodiment of the present invention, it is possible to minimize the deformation of members due to heat generated in a process of transmitting microwaves.

Furthermore, according to the exemplary embodiment of the present invention, it is possible to efficiently replace a transmission plate.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a diagram schematically illustrating a general substrate treating apparatus.

FIG. 2 is a diagram schematically illustrating a substrate treating apparatus according to an exemplary embodiment of the present invention.

FIG. 3 is an exploded perspective view of a microwave application unit according to the exemplary embodiment of FIG. 2.

FIG. 4 is a diagram schematically illustrating a support plate and a first waveguide of FIG. 2, when viewed from the top.

FIGS. 5A and 5B are diagrams schematically illustrating a state in which microwaves flow in a first transmission plate and the first waveguide of FIG. 2.

FIGS. 6 and 7 are diagrams schematically illustrating a first waveguide according to another exemplary embodiment of FIG. 2, when viewed from the top.

FIG. 8 is a diagram schematically illustrating a substrate treating apparatus according to another exemplary embodiment of the present invention.

FIG. 9 is a perspective view schematically illustrating a support plate, a first waveguide, a second waveguide, and a third waveguide according to the exemplary embodiment of FIG. 8.

FIG. 10 is a diagram schematically illustrating the support plate, the first waveguide, the second waveguide, and the third waveguide of FIG. 9, when viewed from the top.

FIG. 11 is a diagram schematically illustrating a support plate, a first waveguide, and a second waveguide according to another exemplary embodiment of FIG. 8.

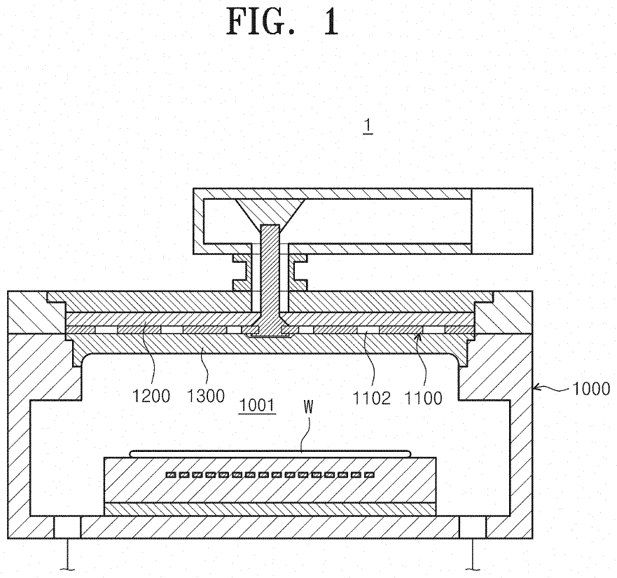

### DETAILED DESCRIPTION

Hereinafter, exemplary embodiments of the present invention will be described in more detail with reference to the accompanying drawings. Exemplary embodiments of the present invention may be modified in various forms and should not be construed that the scope of the present invention is limited to exemplary embodiments to be described below. The exemplary embodiments will be provided for more completely explaining the present invention to those skilled in the art. Therefore, shapes, and the like of components in the drawings are exaggerated to emphasize a more clear description.

Terms, such as first and second, are used for describing various constituent elements, but the constituent elements are not limited by the terms. The terms are used only for distinguishing one component from the other component. For example, without departing from the scope of the invention, a first constituent element may be named as a second constituent element, and similarly a second constituent element may be named as a first constituent element.

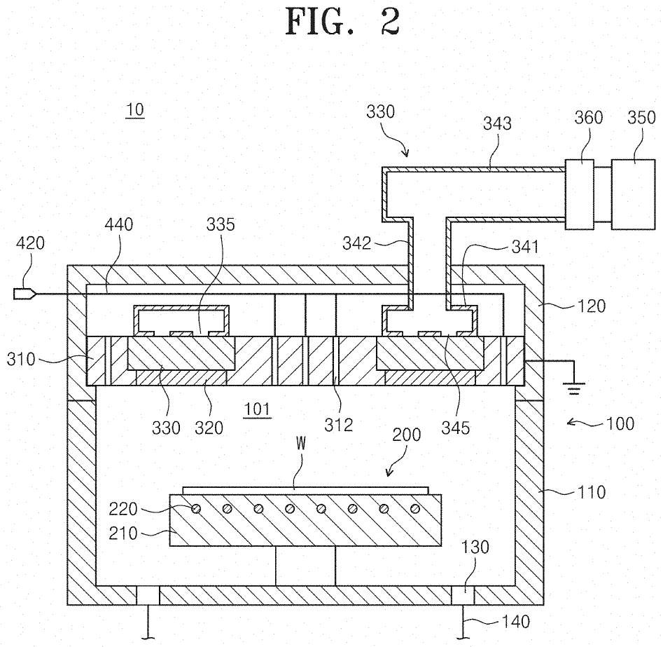

Hereinafter, an exemplary embodiment of the present invention will be described in detail with reference to FIGS. 2 to 11.

FIG. 2 is a diagram schematically illustrating a substrate treating apparatus according to an exemplary embodiment of the present invention. Referring to FIG. 2, a substrate treating apparatus 10 treats a substrate W. The substrate treating apparatus 10 may treat the substrate W using plasma. For example, the substrate treating apparatus 10 may perform an etching process for removing a thin film on the substrate W using plasma, an ashing process for removing a photoresist film, a deposition process of forming a thin film on the substrate W, or a dry cleaning process.

Optionally, the substrate treating apparatus 10 may perform an annealing process on the substrate W using hydrogen plasma. However, the present invention is not limited thereto, and the plasma treating process performed by the substrate treating apparatus 10 may be variously modified into known plasma treating processes. The substrate W on which the treating process has been partially performed may be carried in as the substrate W carried in the substrate treating apparatus 10. For example, the substrate W carried in the substrate treating apparatus 10 may be a substrate W on which an etching process, a photolithography process, or the like is performed.

The substrate treating apparatus 10 may include a process chamber 100, a support unit 200, a microwave application unit 300, and a gas supply unit 400.

The process chamber 100 may include a body 110 and a cover 120. The body 110 has an opened upper surface and may have an inner space. For example, the body 110 may have an inner space and have a cylindrical shape with an opened upper surface. The cover 120 may be disposed on an upper end of the body 110. The cover 120 may seal the opened upper surface of the body 110. For example, the cover 120 may be provided in a cylindrical shape with an opened lower surface. The process chamber 110 may be defined by combining the body 110 and the cover 120 with each other. The cover 120 may be provided with a stepped inner side of a lower end so that an upper space has a larger radius than a lower space. An outer end of a support plate 310 to be described below may be disposed at the stepped portion inside the lower end of the cover 120.

The process chamber 100 has a treating space 101 therein. The treating space 101 is provided as a space formed by combining the body 110, the cover 120, and the support plate 310 to be described below with each other. The treating space 101 provides a space in which the substrate W is to be treated.

However, unlike the above-described example, the cover 120 may not be provided in the process chamber 100 according to the exemplary embodiment of the present invention. For example, the body 110 and the support plate 310 may be combined with each other to provide the treating space 101. The body 110 may have an opened upper surface, and the support plate 310 may seal the opened upper surface of the body 110. The outer end of the support plate 310 may be coupled to an outer upper end of the body 110 to define the treating space 101.

An opening (not illustrated) through which the substrate W is carried out from the treating space 101 or the substrate W is carried into the treating space 101 is formed in a side wall of the process chamber 100. The opening (not illustrated) may be selectively shielded by a door (not illustrated). For example, the opening (not illustrated) may be formed in one side wall of the body 110. The inner wall of the process chamber 100 may be coated. For example, the inner wall of the process chamber 100 may be coated with a material including quartz.

An exhaust hole 130 is formed in a bottom surface of the process chamber 100. For example, the exhaust hole 130 may be formed in a bottom surface of the body 110. The exhaust hole 130 may be connected with an exhaust line 140. The exhaust line 140 discharges particles, process by-products, and the like flowing in the treating space 101. One end of the exhaust line 140 is connected to the exhaust hole 130, and the other end of the exhaust line 140 is connected to a decompression unit (not illustrated) providing a negative pressure. The decompression unit (not illustrated) may be a pump. However, the present invention is not limited thereto, and the decompression unit (not illustrated) may be provided to be variously modified as known devices for providing a negative pressure.

The support unit 200 may be positioned in the treating space 101. The support unit 200 may support the substrate W in the treating space 101. According to an exemplary embodiment, the support unit 200 may be an ESC capable of chucking the substrate W using an electrostatic force. Optionally, the support unit 200 may physically support the substrate W by mechanical clamping. Optionally, the support unit 200 does not provide a means for fixing the substrate W, and the substrate W may be disposed on the support unit 200.

The support unit 200 may include a body 210 and a heater 220. The body 210 supports the substrate W. An upper surface of the body 210 may be provided as a support surface for supporting the substrate W. The substrate W is seated on the upper surface of the body 210. The body 210 may be provided with a dielectric substance. The body 210 may be provided as a dielectric plate having a substantially disk shape. According to an exemplary embodiment, the diameter of the upper surface of the body 210 may be provided relatively larger than the diameter of the substrate W.

The heater 220 heats the substrate W. The heater 220 may heat the substrate W supported on the upper surface of the body 210. The heater 220 may heat the substrate W by increasing the temperature of the body 210. For example, the heater 220 may be provided as a heating element that generates heat by resisting an applied current. The heater 230 may be a heating element such as tungsten. However, a type of the heater 230 is not limited thereto, and may be provided to be variously modified as known heating elements.

The generated heat may be transmitted to the substrate W through the body 210. The substrate W may be maintained at a predetermined temperature required for the process by the heat generated in the heater 220. In addition, the heater 220 may increase the temperature of the body 210 so as to prevent impurities (e.g., an oxide film) separated from the substrate W from re-adhering to the substrate W while the substrate W is treated.

Although not illustrated, according to an exemplary embodiment, a plurality of heaters 220 may be provided as spiral coils. The heaters 220 may be provided in different regions of the body 210, respectively. For example, the heater 220 for heating a central region of the body 210 and the heater 220 for heating an edge region of the body 210 may be provided, respectively, and these heaters 220 may each independently adjust the degree of heat generation.

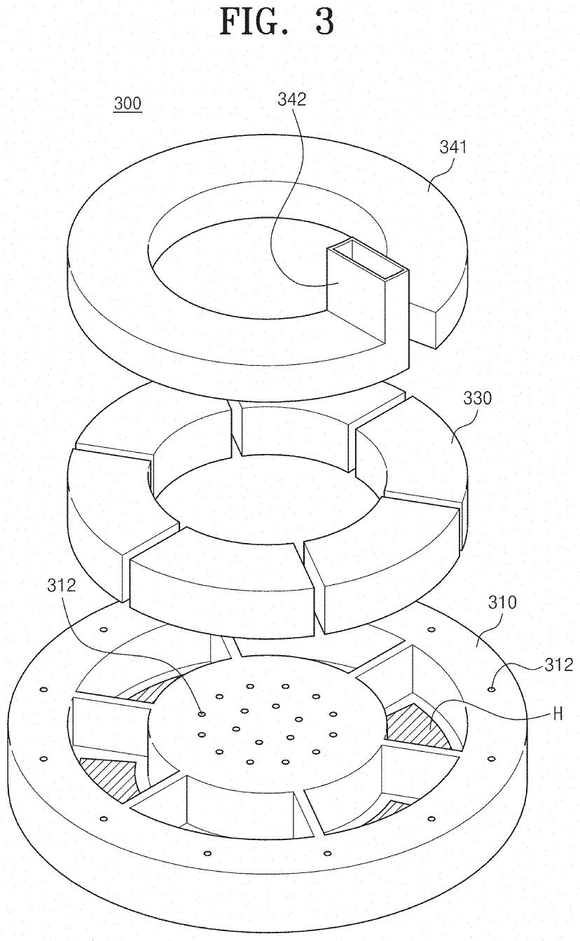

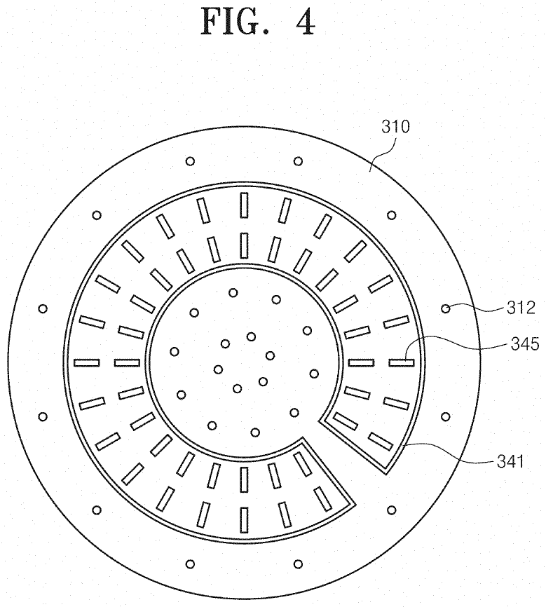

FIG. 3 is an exploded perspective view of a microwave application unit according to the exemplary embodiment of FIG. 2. FIG. 4 is a diagram schematically illustrating the support plate and the first waveguide of FIG. 2 when viewed from the top. Hereinafter, the microwave application unit according to the exemplary embodiment of the present invention will be described in detail with reference to FIGS. 2 to 4.

The microwave application unit 300 generates plasma in the treating space 101. The microwave application unit 300 may apply microwaves to treating gas supplied to the treating space 101 to excite the treating gas in the treating space 101. The microwave application unit 300 may include a support plate 310, a first transmission plate 330, a first waveguide 340, a first power supply 350, and a first matching network 360.

The support plate 310 is disposed above the support unit 200. The support plate 310 may be combined with the body 110 and the cover 120 to define the treating space 101. The support plate 310 functions as an upper wall of the treating space 101. The support plate 310 may be provided in a plate shape. For example, the support plate 310 may be provided in a disk shape having a substantially thickness. An outer lower end of the support plate 310 may be disposed in a stepped space of the cover 120. A lower surface of the support plate 310 may be provided flat. However, the present invention is not limited thereto, and an edge region of the lower surface of the support plate 310 may be formed to protrude downwards.

A groove H is formed in the support plate 310. The groove H may be formed to be recessed at a predetermined distance from the upper surface of the support plate 310. The groove H may be formed in an edge region of the support plate 310 when viewed from the top. A plurality of grooves H may be formed. The plurality of grooves H may be formed in the edge region of the support plate 310 to be spaced apart from each other along a circumferential direction of the support plate 310. The height of the groove H may correspond to the height of the first transmission plate 330 to be described below. In addition, the width of the groove H may correspond to the width of the first transmission plate 330. For example, when viewed from the top, the groove H and the first transmission plate 330 may have a shape that coincides with each other. Accordingly, the first transmission plate 330 may be inserted into the plurality of grooves H formed in the support plate 310.

The support plate 310 may be provided with a material containing metal. The support plate 310 may be grounded. Optionally, although not illustrated, high-frequency power may be applied to the support plate 310. A region 320 of the support plate 310 corresponding to the lower portion of the groove H formed in the support plate 310 may not be provided with a metal material. For example, the region 320 corresponding to the lower portion of the groove H of the support plate 310 may be provided with a material (e.g., quartz) capable of transmitting microwaves.

A gas channel 312 is formed in the support plate 310. The gas channel 312 may be provided as a groove penetrating from the upper end to the lower end of the support plate 310. The gas channel 312 may communicate with a gas line 440 to be described below. The treating gas supplied from the gas supply unit 400 to be described below sequentially passes through the gas line 440 and the gas channel 312 to be supplied to the treating space 101.

A plurality of gas channels 312 may be provided. The plurality of gas channels 312 may be formed in a region including the center of the support plate 310 and an edge region of the support plate 310. The plurality of gas channels 312 may be formed to be spaced apart from each other along the circumferential direction of the support plate 310. The plurality of gas channels 312 are formed at positions that do not overlap with the first waveguide 330 to be described below when viewed from the top.

The first transmission plate 330 transmits a first microwave received from the first waveguide 340 to be described below to the treating space 101. The first transmission plate 330 may be disposed at a position corresponding to the edge region of the support plate 310 when viewed from the top. The first transmission plate 330 is inserted into the groove H. The first transmission plate 330 may have a shape corresponding to the groove H when viewed from the top. In addition, the first transmission plate 330 may have a height corresponding to the height of the groove H. A plurality of first transmission plates 330 may be provided. For example, the first transmission plate 330 may be provided in the number corresponding to the plurality of grooves H formed in the support plate 310. The plurality of first transmission plates 330 may be inserted into the plurality of grooves H, respectively. When viewed from the top, the plurality of first transmission plates 330 may be combined with each other to have a ring shape.

The first transmission plate 330 is provided with a material that may transmit microwaves. The first transmission plate 330 is provided with a material that radiates the microwaves to the treating space 101. For example, the first transmission plate 330 may be provided with a material including quartz. Optionally, the first transmission plate 330 may be provided with a dielectric material, such as aluminum oxide (Al₂O₃), aluminum nitride (AlN), sapphire, or silicon nitride (SiN).

The first waveguide 340 is disposed above the first transmission plate 330. The first waveguide 340 is positioned to be in contact with the first transmission plate 330. For example, the lower surface of the first waveguide 340 may be in surface contact with the upper surface of the first transmission plate 330. The first waveguide 340 may be disposed to overlap with the first transmission plate 330, when viewed from the top. The first waveguide 340 may be formed in a ring shape when viewed from the top. For example, the first waveguide 340 may have a ring shape with a cut portion, when viewed from the top.

The first waveguide 340 may be provided with a metal material. For example, the first waveguide 340 may be provided with a material including copper or aluminum. An inner surface of the first waveguide 340 is provided as a conductor. For example, the inner surface of the first waveguide 340 may be provided with gold or silver. The first waveguide 340 may be provided in a pipe shape with a polygonal cross section. The first waveguide 340 has a passage formed therein. The first microwave applied from the first power supply 350 to be described below may be transmitted to the first transmission plate 330 through an inner passage of the first waveguide 340.

The first waveguide 340 may have a first portion 341, a second portion 342, and a third portion 343. The first portion 341, the second portion 342, and the third portion 343 may be integrally formed. The first portion 341 may be provided in a ring shape. The first portion 341 may have an annular ring shape with respect to the center of the support plate 310. The first portion 341 may be disposed at a position facing the edge region of the support plate 310, when viewed from the top. The first portion 341 is formed with a cut part. The first portion 341 may be provided in a discontinuous ring shape.

A first slot 345 is formed on a bottom surface of the first portion 341. The first slot 345 may be provided as a through slit passing through the bottom surface of the first portion 341. Optionally, the first slot 345 may be filled with a material that transmits the first microwave. A longitudinal direction of the first slot 345 may be formed in a direction from one side surface of the first portion 341 toward the other side surface facing one side surface.

A plurality of first slots 345 may be provided. The plurality of first slots 345 may be disposed to be spaced apart from each other along a circumferential direction of the first portion 341. The plurality of first slots 345 may be disposed in a plurality of rows when viewed from a front cross-section of the first portion 341. Accordingly, the plurality of first slots 345 may be arranged in a plurality of ring shapes in the first portion 341. Unlike illustrated the drawings, the plurality of first slots 345 may also be arranged at different angles with respect to the center of the support plate 310.

The first slot 345 may be provided to be opened and closed. For example, a member (not illustrated) may slide in the first slot 345 to open and close the first slot 345. The plurality of first slots 345 may be opened and closed, respectively. Accordingly, the plurality of first slots 345 are opened and closed, respectively, thereby controlling the intensity of a microwave to be transmitted for each region of the treating space 101.

The second portion 342 may extend from the first portion 341. For example, the second portion 342 may extend upwards from the upper surface of the first portion 341. The second portion 342 may be coupled to the upper surface of the first portion 341 at a position adjacent to the cut surface formed in the first portion 341.

The third portion 343 may extend from the second portion 342. For example, the third portion 343 may extend from the upper surface of the second portion 332 in a horizontal direction. The third portion 343 may be connected to the first power supply 350 to be described below.

The first power supply 350 generates a first microwave. The first power supply 350 may be connected to the first waveguide 340. For example, the first microwave generated by the first power supply 350 may have a frequency of approximately 2.3 GHz to 2.5 GHz. The first matching network 360 may be provided between the first power supply 350 and the first waveguide 340. The first matching network 360 may match the first microwave transmitted through the first power supply 350 with a predetermined frequency.

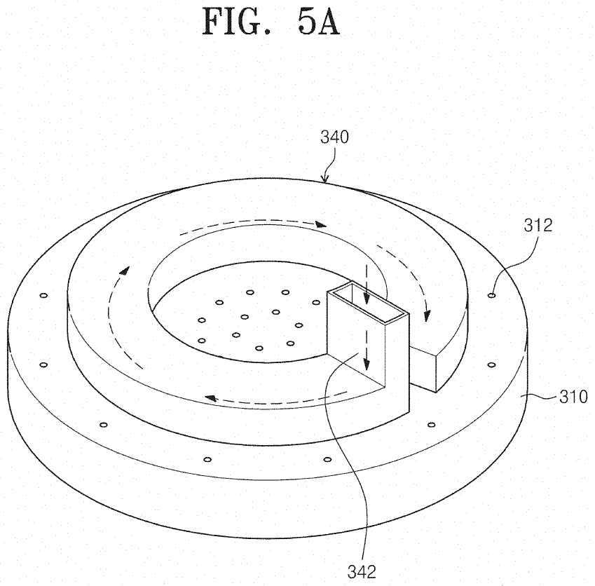

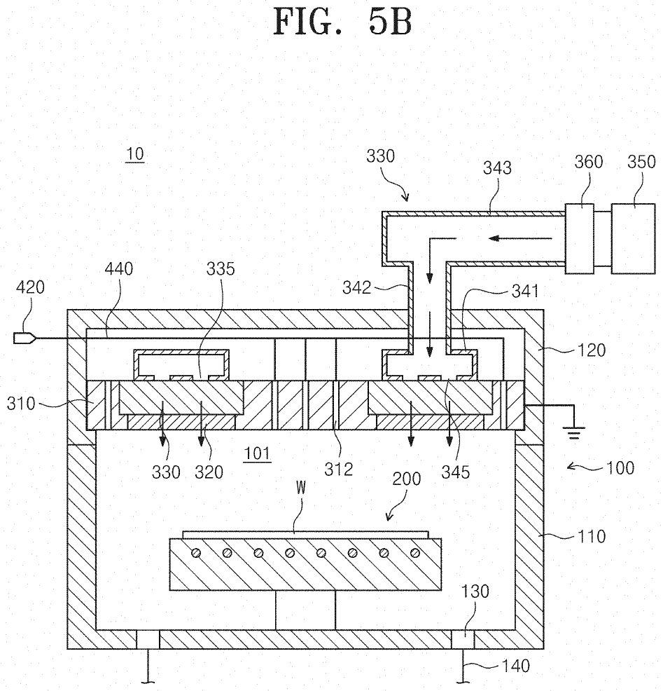

FIGS. 5A and 5B are diagrams schematically illustrating a state in which microwaves flow in the first transmission plate and the first waveguide of FIG. 2. Referring to FIGS. 5A and 5B, the first microwave generated from the first power supply 350 may be transmitted to the first waveguide 340. The first microwave generated from the first power supply 350 may be transmitted to the first portion 340 through the first matching network 360, and the third portion 343 and the second portion 341 of the first waveguide 342. The first microwave transmitted to the first portion 341 may be transmitted to the cut portion of the first portion 341 along the first portion 341 formed in a ring shape. The first microwave is transmitted in an inner space of the first portion 341, and transmitted to the first transmission plate 330 in surface contact with the first slot 345 by passing through the first slot 345 formed on the lower surface of the first portion 341. The first microwave may be radiated from the first transmission plate 330 to be transmitted to the treating space 101.

According to the exemplary embodiment of the present invention, the microwave application unit 300 may be provided to include the support plate 310 disposed above the processing space 101, a first transmission plate 330 inserted into the groove H formed in the support plate 310, and the first waveguide 340 disposed to be in surface contact with the first transmission plate 330. Accordingly, the first waveguide 340 directly transmits the microwaves to the first transmission plate 330, thereby minimizing the structural complexity of the upper region of the treating space 101 in which the microwave application unit 300 is disposed. That is, since the first waveguide 340 according to the exemplary embodiment of the present invention functions as an antenna, a separate antenna member is not installed to eliminate the structural complexity.

In addition, by adopting the structure in which the first transmission plate 330 receiving the first microwave from the first waveguide 340 is inserted into the groove H formed in the support plate 310, when the first transmission plate 330 is deformed due to heat generation or the like, maintenance may be easily performed. In addition, when viewed from the top, the first transmission plate 330 and the first waveguide 340 are disposed at a position facing the edge region of the treating space 101, thereby alleviating a phenomenon in which the microwaves are concentrated in the central region of the treating space 101. Accordingly, since the microwaves may be uniformly transmitted to the treating space 101, plasma may be uniformly formed in the treating space 101.

Referring back to FIG. 2, the gas supply unit 400 supplies the treating gas to the treating space 101. The gas supply unit 400 may include a gas supply source 420 and a gas line 440. The gas supply source 420 may store and/or supply treating gas. The treating gas may include hydrogen. The gas line 440 is connected with the gas supply source 420 and a gas channel 312. One end of the gas line 440 may be connected to the gas supply source 420, and the other end of the gas line may communicate with the gas channel 312. The treating gas supplied from the gas supply unit 420 may be supplied to the treating space 101 through the gas line 440 and the gas channel 312. For example, the treating gas may be supplied toward the upper portion of the substrate W supported by the support unit 200.

In the above-described example, it has been described that the other end of the gas line 440 communicates with the gas channel 312 formed in the support plate 310 as an example. However, the present invention is not limited thereto, and the other end of the gas line 440 may be branched. The branched other end of the gas line 440 may be coupled to the gas channel 312 and one side wall of the process chamber 100, respectively. The other end of the gas channel 312 coupled to one side wall of the process chamber 100 may supply the treating gas toward the treating space 101 from a side surface of the treating space 101. The other end of the gas channel 312 may be coupled to a plurality of points along a circumferential direction of one side wall of the process chamber 100.

According to the exemplary embodiment of the present invention described above, the treating gas may be supplied toward the upper portion of the treating space 101 along the gas channel 312 formed in the support plate 310. Accordingly, it is possible to efficiently generate plasma applied to the substrate W in the treating space 101, and to improve the treating efficiency of the substrate W.

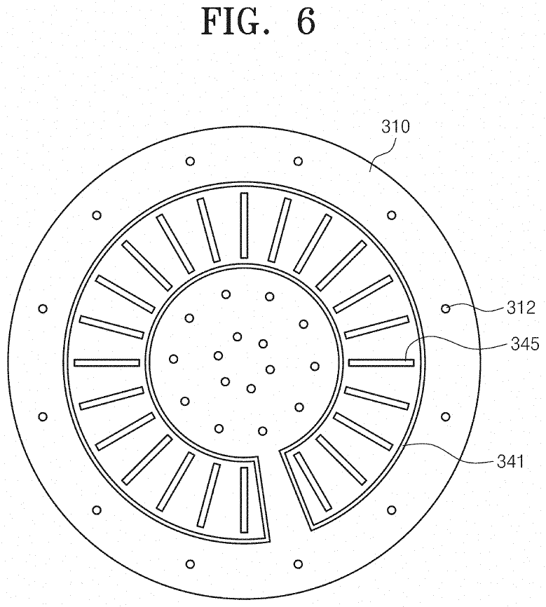

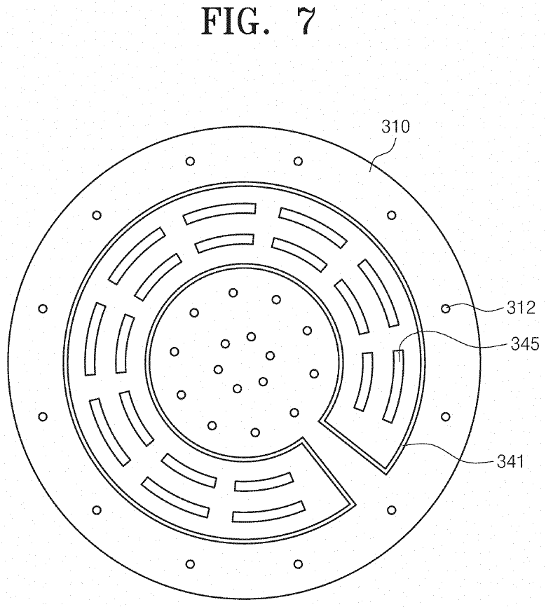

FIGS. 6 and 7 are diagrams schematically illustrating a first waveguide according to another exemplary embodiment of FIG. 2 when viewed from the top.

The first waveguide according to an exemplary embodiment to be described below is provided in a structure mostly similar to that of the first waveguide described with reference to FIGS. 2 to 4 except for a case to be additionally described. Accordingly, the description of the duplicated configuration will be omitted.

Referring to FIG. 6, a first slot 345 is formed on a bottom surface of the first portion 341. The first slot 345 may be provided as a through slit passing through the upper and lower surfaces of the first portion 341. Optionally, the first slot 345 may be filled with a material that transmits microwaves. A longitudinal direction of the first slot 345 may be formed in a direction parallel with the other side surface facing one side surface from one side surface of the first portion 341. A plurality of first slots 345 may be provided. The plurality of first slots 345 may be disposed to be spaced apart from each other along the circumferential direction of the first portion 341. Unlike illustrated the drawings, the plurality of first slots 345 may be arranged at different angles with respect to the center of the support plate 310.

Referring to FIG. 7, the longitudinal direction of the first slot 345 formed on the bottom surface of the first portion 341 may be formed along the circumferential direction of the first portion 341. For example, the first slot 345 may have a longitudinal direction in a direction parallel to one side surface of the first portion 341. A plurality of first slots 345 may be provided. The plurality of first slots 345 may be disposed to be spaced apart from each other along the circumferential direction of the first portion 341. The plurality of first slots 345 may be disposed in a plurality of rows when viewed from a front cross-section of the first portion 341. Accordingly, the plurality of first slots 345 may be arranged in a plurality of ring shapes in the first portion 341. Unlike illustrated the drawings, the plurality of first slots 345 may be arranged at different angles with respect to the center of the support plate 310.

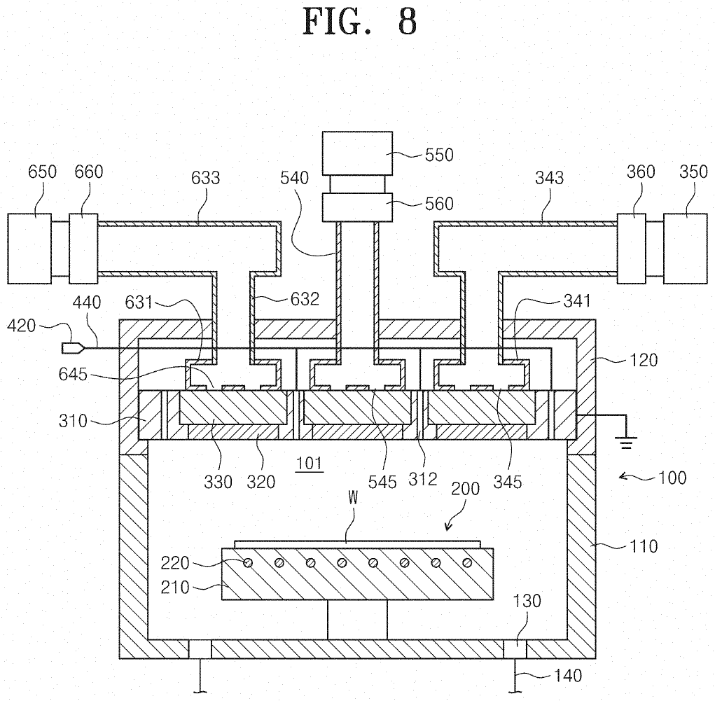

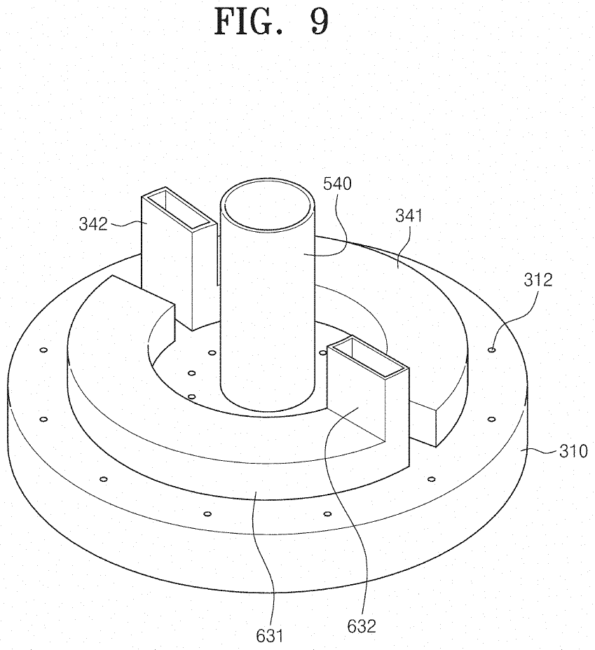

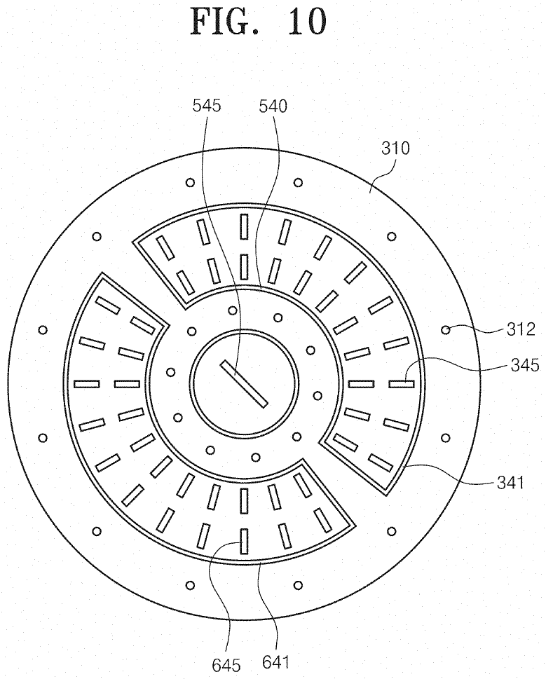

FIG. 8 is a diagram schematically illustrating a substrate treating apparatus according to another exemplary embodiment of the present invention. FIG. 9 is a perspective view schematically illustrating a support plate, a first waveguide, a second waveguide, and a third waveguide according to the exemplary embodiment of FIG. 8. FIG. 10 is a diagram schematically illustrating the support plate, the first waveguide, the second waveguide, and the third waveguide of FIG. 9, when viewed from the top. Hereinafter, a substrate treating apparatus according to another exemplary embodiment of the present invention will be described in detail with reference to FIGS. 8 to 10.

The microwave application unit 300 includes a support plate 310, a first transmission plate 330, a first waveguide 340, a first power supply 350, a second transmission plate 530, a second waveguide 540, a second power supply 550, a third transmission plate 630, a third waveguide 640, and a third power supply 650.

A groove H and a central groove CH may be formed in the support plate 310. The groove H may be formed to be recessed at a predetermined distance from the upper surface of the support plate 310. The groove H may be formed in an edge region of the support plate 310 when viewed from the top. A plurality of grooves H may be formed. The plurality of grooves H may be formed in the edge region of the support plate 310 to be spaced apart from each other along a circumferential direction of the support plate 310.

The groove H may have a first groove H1 and a second groove H2. The first groove H1 may be formed in a part of the circumferential direction of the edge region of the support plate 310. For example, the first groove H1 may be formed on one side of a virtual straight line passing through the center of the support plate 310. The first transmission plate 330 may be inserted into the first groove H1. The first groove H1 may have a shape corresponding to the first transmission plate 330 when viewed from the top. In addition, the height of the first groove H1 may correspond to the height of the first transmission plate 330.

The second groove H2 may be formed in the other part of the circumferential direction of the edge region of the support plate 310. For example, the second groove H2 may be formed on the other side of the virtual straight line passing through the center of the support plate 310. The first groove H1 and the second groove H2 may be formed in regions symmetrical to each other on the support plate 310, when viewed from the top. The third transmission plate 630 to be described below may be inserted into the second groove H2. The second groove H2 may have a shape corresponding to the third transmission plate 630, when viewed from the top. In addition, the height of the second groove H2 may correspond to the height of the third transmission plate 630. The first groove H1 and the second groove H2 may be combined with each other to have a substantially ring shape when viewed from the top.

The central groove CH may be formed in a region including the center of the support plate 310. The central groove CH may be formed to be spaced apart from the first groove H1 and the second groove H2. The second transmission plate 530 to be described below may be inserted into the central groove CH. The central groove CH may have a shape corresponding to the second transmission plate 530, when viewed from the top. In addition, the height of the central groove CH may correspond to the height of the second transmission plate 530.

One region of the support plate 310 corresponding to each of the lower surfaces of the first groove H1, the second groove H2, and the central groove CH may be provided with a material that may transmit the microwaves. For example, each of the regions 320 corresponding to the lower portion of the first groove H1, the lower portion of the second groove H2, and the lower portion of the central groove CH of the support plate 310 may be provided with a material (e.g., quartz) that may transmit the microwaves.

The first waveguide 340 may have a first portion 341, a second portion 342, and a third portion 343. The first portion 341, the second portion 342, and the third portion 343 may be integrally formed.

The first portion 341 may be provided in a substantially ring shape. The first portion 341 may be provided in a cut ring shape. The first portion 341 may be provided in a semicircular shape at a position facing an edge region of the support plate 310 with respect to the center of the support plate 310. For example, the first portion 341 may be provided to surround a part of an upper edge region of the support plate 310 on which the first transmission plate 330 inserted into the first groove H1 is disposed. The second portion 342 extends from the first portion 341, and the third portion 343 extends from the second portion 342. Since the second portion 342 and the third portion 343 are provided mostly similar to the description of the second portion 342 and the third portion 343 described with reference to FIGS. 2 to 4, the description thereof will be omitted.

The second transmission plate 530 transmits a second microwave received from the second waveguide 540 to be described below to the treating space 101. The second transmission plate 530 may be disposed at a position corresponding to a region including the center of the support plate 310 when viewed from the top. For example, the second transmission plate 530 may be disposed at a position overlapping with the center of the substrate W supported by the support unit 200, when viewed from the top. The second transmission plate 530 is inserted into the central groove CH.

The second transmission plate 530 is provided with a material that may transmit the microwaves. The second transmission plate 530 is provided with a material that radiates the microwaves to the treating space 101. For example, the second transmission plate 530 may be provided with a material including quartz to radiate the microwaves to the central region of the treating space 101. Optionally, the second transmission plate 530 may be provided with a dielectric material, such as aluminum oxide (Al₂O₃), aluminum nitride (AlN), sapphire, or silicon nitride (SiN).

The second waveguide 540 is disposed above the second transmission plate 530. The second waveguide 540 is positioned to be in contact with an upper surface of the second transmission plate 530. For example, a lower surface of the second waveguide 540 may be in surface contact with the upper surface of the second transmission plate 530. The second waveguide 540 may be disposed to overlap with the second transmission plate 530, when viewed from the top. The second waveguide 540 may overlap with the center of the substrate W positioned in the support unit 200, when viewed from the top.

The second waveguide 540 may be disposed to be spaced apart from the first waveguide 340 and the third waveguide 640 to be described below. A gas line 440 may be disposed in a space in which the first waveguide 340, the second waveguide 540, and the third waveguide 640 are spaced apart from each other. Accordingly, a gas channel 312 may be formed on an upper surface of the support plate 310 facing a position in which the first waveguide 340, the second waveguide 540, and the third waveguide 640 are spaced apart from each other. Accordingly, when viewed from the top, the gas channel 312 may be formed at a position that does not overlap with the first waveguide 340, the second waveguide 540, and the third waveguide 640 to supply the treating gas to the upper portion of the treating space 101.

A second slot 545 is formed on the lower surface of the second waveguide 540. The second slot 545 may pass through the lower surface of the second waveguide 540. Optionally, the second slot 545 may be filled with a material that transmits a second microwave to be described below. At least one or more second slots 545 may be provided. The second slot 545 may be provided at a position overlapping with the center of the substrate W supported by the support unit 200, when viewed from the top. According to an exemplary embodiment, the second slot 545 may be provided to be opened and closed similarly to the first slot 345.

The second power supply 550 generates a second microwave. For example, the second microwave generated by the second power supply 550 may have a frequency of approximately 0.8 GHz to 1.2 GHz. The second matching network 560 is provided in the second waveguide 540. The second matching network 560 is provided between the second power supply 550 and the second waveguide 540. The second matching network 560 may match the second microwave transmitted through the second power supply 550 with a predetermined frequency.

The third transmission plate 630 is inserted into the second groove H2. The third transmission plate 630 is provided similarly to the structure of the first transmission plate 330. Accordingly, a detailed description thereof will be omitted to avoid the duplicated contents.

The third waveguide 640 may have a first portion 641, a second portion 642, and a third portion 643. The first portion 641, the second portion 642, and the third portion 643 may be integrally formed. The first portion 641 may be provided in a substantially ring shape. The first portion 641 may be provided in a cut ring shape. The first portion 641 may be provided in a semicircular shape at a position facing the edge region of the support plate 310 with respect to the center of the support plate 310. For example, the first portion 641 may be provided to surround the other part of the upper edge region of the support plate 310 on which the third transmission plate 630 inserted into the second groove H2 is disposed. The first portion 641 of the third waveguide 640 and the first portion 341 of the first waveguide 340 may be combined with each other to form a ring shape, when viewed from the top. One end of the first portion 641 of the third waveguide 640 may be spaced apart from one end of the first portion 341 of the first waveguide 340 by a predetermined distance to face each other. In addition, the other end of the first portion 641 of the third waveguide 640 may be spaced apart from the other end of the first portion 341 of the first waveguide 340 by a predetermined distance to face each other.

A third slot 645 is formed on a bottom surface of the first portion 641. The third slot 645 may be provided as a through slit passing through the bottom surface of the first portion 641. Optionally, the third slot 645 may be filled with a material that transmits a third microwave to be described below. The longitudinal direction, arrangement, and/or shape of the third slot 645 may be provided to be mostly similar to those of the first slot 345. Accordingly, the description of the longitudinal direction, arrangement, and/or shape of the third slot 645 will be omitted to avoid the description of the duplicated contents.

The second portion 642 may extend from the first portion 641. For example, the second portion 642 may extend upwards from the upper surface of the first portion 641. The second portion 642 may be positioned on a virtual straight line passing through the center of the support plate 310. For example, the second portion 342 of the first waveguide 340 may be positioned to face the second portion 642 of the third waveguide 640 on the virtual straight line.

The third portion 643 may extend from the second portion 642. For example, the third portion 643 may extend from the upper surface of the second portion 642 in a vertical direction. The third portion 643 may be connected to the third power supply 650 to be described below.

The third power supply 650 generates a third microwave. The third power supply 650 may be connected to the third waveguide 640. For example, the third microwave generated by the third power supply 650 may have a frequency of approximately 2.3 GHz to 2.5 GHz. The third matching network 660 is provided in the third waveguide 640. The third matching network 660 is provided between the third power supply 650 and the third waveguide 640. The third matching network 660 may match the third microwave transmitted through the third power supply 650 with a predetermined frequency.

The first microwave generated from the first power supply 350 may have a first intensity. The second microwave generated from the second power supply 550 may have a second intensity. In addition, the third microwave generated from the third power supply 650 may have a third intensity. The first intensity, the second intensity, and the third intensity may have different sizes. Optionally, the first intensity and the third intensity may have sizes corresponding to each other, and the second intensity may have a smaller size than the first intensity and the third intensity.

According to the exemplary embodiment of the present invention described above, the first transmission plate 330, the second transmission plate 530, and the third transmission plate 630 are inserted into the first groove H1 and the second groove H2 formed in the upper edge region of the support plate 310 and the central groove CH formed in the region including the center of the support plate 310, respectively. In addition, the first waveguide 340 through which the first microwave is transmitted is disposed in the first transmission plate 330, the second waveguide 540 through which the second microwave is transmitted is disposed in the second transmission plate 530, and the third waveguide 640 through which the third microwave is transmitted is disposed in the third transmission plate 630. Accordingly, the intensities of the microwaves transmitted to the treating space 101 from each of the first waveguide 340, the second waveguide 540, and the third waveguide 640 may be varied. The intensities of the microwaves may be individually controlled according to the process of treating the substrate W. Accordingly, the uniformity of plasma in the treating space 101 may be compensated by controlling the supply of microwaves having different sizes according to the size of plasma formed for each region of the treating space 101.

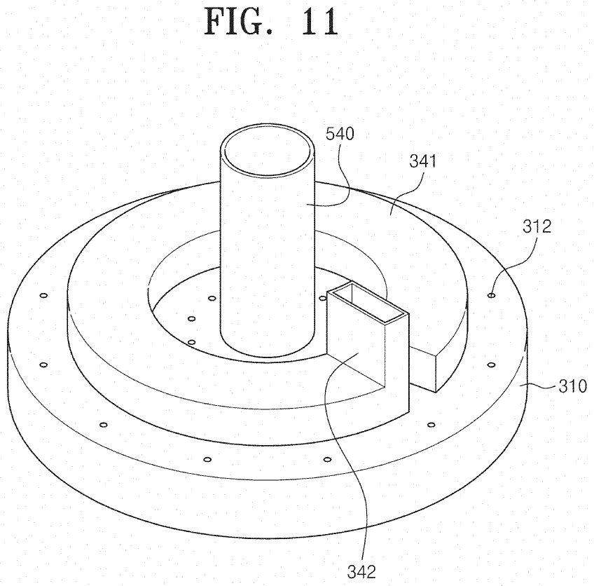

FIG. 11 is a diagram schematically illustrating a support plate, a first waveguide, and a second waveguide according to another exemplary embodiment of FIG. 8. Referring to FIG. 11, the microwave application unit 300 may include a support plate 310, a first transmission plate 330, a first waveguide 340, a first power supply 350, a second transmission plate 530, a second waveguide 540, and a second power supply 550.

A groove H is formed in the support plate 310. The groove H may be formed to be recessed at a predetermined distance from the upper surface of the support plate 310. The groove H may be formed in an edge region of the support plate 310 when viewed from the top. A plurality of grooves H may be formed. The plurality of grooves H may be formed in the edge region of the support plate 310 to be spaced apart from each other along a circumferential direction of the support plate 310. The height of the groove H may correspond to the height of the first transmission plate 330 to be described below. In addition, the width of the groove H may correspond to the width of the first transmission plate 330 to be described below. For example, when viewed from the top, the groove H and the first transmission plate 330 may have a shape that coincides with each other. Accordingly, the first transmission plate 330 may be inserted into the plurality of grooves H formed in the support plate 310.

The first waveguide 340 is disposed above the first transmission plate 330. The first waveguide 340 is positioned to be in contact with the first transmission plate 330. For example, the lower surface of the first waveguide 340 may be in surface contact with the upper surface of the first transmission plate 330. The first waveguide 340 may be disposed to overlap with the first transmission plate 330, when viewed from the top. The first waveguide 340 may be formed in a ring shape, when viewed from the top. For example, the first waveguide 340 may have a ring shape with a cut portion, when viewed from the top.

The first power supply 350, the second transmission plate 530, the second waveguide 540, and the second power supply 550 are provided mostly similar to the first power supply 350, the second transmission plate 530, the second waveguide 540, and the second power supply 550 described with reference to FIGS. 9 and 10, and thus, a description thereof will be omitted.

The foregoing detailed description illustrates the present invention. Further, the above content shows and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A substrate treating apparatus for treating a substrate, comprising:
a process chamber having a treating space therein;
a support unit configured to support the substrate in the treating space;
a gas supply unit configured to supply treating gas to the treating space; and
a microwave application unit configured to apply microwaves to the treating gas to generate plasma,
wherein the microwave application unit comprises a first power supply configured to apply a first microwave;
a support plate having a groove formed on an upper surface thereof and combined with the process chamber above the support unit to define the treating space;
a first transmission plate inserted into the groove to radiate the first microwave to the treating space; and
a first waveguide disposed to overlap with an upper portion of the first transmission plate and coupled to the first power supply,
wherein a plurality of grooves is provided, and
the plurality of grooves are formed along a circumferential direction in an edge region of the support plate, when viewed from the top.

2. The substrate treating apparatus of claim 1,
wherein a plurality of first transmission plates is provided, and
the plurality of first transmission plates are combined with each other to have a ring shape, when viewed from the top.

3. The substrate treating apparatus of claim 2,
wherein the first waveguide is formed in a ring shape when viewed from the top.

4. The substrate treating apparatus of claim 3,
wherein a plurality of first slots is formed on a lower surface of the first waveguide, and
the plurality of first slots are spaced apart from each other along a circumferential direction of the first waveguide.

5. The substrate treating apparatus of claim 4,
wherein the plurality of first slots are disposed in a plurality of rows when viewing the first waveguide from a front cross section.

6. The substrate treating apparatus of claim 5,
wherein the plurality of first slots are provided to be opened and closed.

7. The substrate treating apparatus of claim 4,
wherein on the upper surface of the support plate, a central groove formed in a region including the center of the support plate is further formed,
wherein the microwave application unit further comprises
a second power supply configured to apply a second microwave;
a second transmission plate inserted into the central groove to radiate the second microwave to the treating space; and
a second waveguide disposed above the second transmission plate and coupled to the second power supply,
wherein at least one or more second slots are formed on a lower surface of the second waveguide.

8. The substrate treating apparatus of claim 7,
wherein the grooves comprise
a first groove formed in a part of the circumferential direction of the edge region of the support plate; and
a second groove formed in the other part of the circumferential direction of the edge region of the support plate,
wherein the first groove and the second groove are combined with each other to form a ring shape.

9. The substrate treating apparatus of claim 8,
wherein the first transmission plate is inserted into the first groove,
wherein the microwave application unit further comprises
a third power supply configured to apply a third microwave;
a third transmission plate inserted into the second groove to radiate the third microwave to the treating space; and
a third waveguide disposed above the third transmission plate and coupled to the third power supply,
wherein a plurality of third slots is formed on a lower surface of the third waveguide, and
the plurality of third slots are spaced apart from each other along a circumferential direction of the third waveguide.

10. The substrate treating apparatus of claim 1, further comprising:
a gas supply unit configured to supply the treating gas to the treating space,
wherein a gas channel through which the treating gas flows is formed in the support plate.

11. The substrate treating apparatus of claim 1,
wherein the support plate is grounded.

12. The substrate treating apparatus of claim 1,
wherein high-frequency power is applied to the support plate.

13. A substrate treating apparatus for treating a substrate comprising:
a chamber having a treating space defined therein;
a support unit configured to support the substrate in the treating space; and
a microwave application unit configured to apply microwaves to treating gas supplied to the treating space to generate plasma,
wherein the microwave application unit comprises
a first power supply configured to apply a first microwave;
a support plate having a groove formed on an upper surface thereof and combined with the chamber above the support unit to define the treating space;
a first transmission plate inserted into the groove to radiate the first microwave to the treating space; and
a first waveguide disposed to overlap with the first transmission plate above the first transmission plate and coupled to the first power supply,
wherein the first waveguide is provided in a ring shape when viewed from the top.

14. The substrate treating apparatus of claim 13,
wherein a plurality of first slots is formed on a lower surface of the first waveguide, and
the plurality of first slots are spaced apart from each other along a circumferential direction of the first waveguide.

15. The substrate treating apparatus of claim 14,
wherein the plurality of first slots are disposed in a plurality of ring shapes.

16. The substrate treating apparatus of claim 15,
wherein a plurality of grooves is provided, and
the plurality of grooves are formed along a circumferential direction in an edge region of the support plate, when viewed from the top,
wherein a plurality of first transmission plates is provided, and
the plurality of first transmission plates are combined with each other to have a ring shape, when viewed from the top.

17. The substrate treating apparatus of claim 16,
wherein on the upper surface of the support plate, a central groove formed in a region including the center of the support plate is further formed,
wherein the microwave application unit further comprises
a second power supply configured to apply a second microwave;
a second transmission plate inserted into the central groove to radiate the second microwave to the treating space; and
a second waveguide disposed above the second transmission plate and coupled to the second power supply,
wherein at least one or more second slots are formed on a lower surface of the second waveguide.

18. The substrate treating apparatus of claim 17,
wherein the grooves comprise
a first groove formed in a part of the circumferential direction of the edge region of the support plate and inserted with the first transmission plate; and
a second groove formed in the other part of the circumferential direction of the edge region of the support plate,
wherein the first groove and the second groove are combined with each other to form a ring shape,
wherein the microwave application unit further comprises
a third power supply configured to apply a third microwave;
a third transmission plate inserted into the second groove to radiate the third microwave to the treating space; and
a third waveguide disposed above the third transmission plate and coupled to the third power supply,
wherein a plurality of third slots is formed on a lower surface of the third waveguide, and
the plurality of third slots are spaced apart from each other along a circumferential direction of the third waveguide.

19. A substrate treating apparatus for treating a substrate comprising:
a process chamber having a treating space formed therein;
a support unit configured to support the substrate in the treating space;
a gas supply unit configured to supply treating gas to the treating space;
a first power supply configured to apply a first microwave;
a second power supply configured to apply a second microwave;
a support plate combined with the process chamber above the support unit to define the treating space;
a first transmission plate disposed above the support plate to radiate the first microwave to the treating space;
a second transmission plate disposed above the support plate to radiate the second microwave to the treating space;
a first waveguide coupled to the first power supply and disposed on an upper surface of the first transmission plate, and having a plurality of first slots formed on a lower surface thereof; and
a second waveguide coupled to the second power supply and disposed on an upper surface of the second transmission plate, and having at least one or more second slots formed on a lower surface thereof,
wherein the upper surface of the support plate has
a central groove formed in a region including the center of the support plate; and
a groove formed in a region facing an edge of the support plate surrounding the central groove,
wherein the first transmission plate is inserted into the groove, and
the second transmission plate is inserted into the central groove.

20. The substrate treating apparatus of claim 19,
wherein a plurality of grooves is provided, and
the plurality of grooves are formed along a circumferential direction of the support plate, when viewed from the top,
wherein a plurality of first transmission plates is provided, and
the plurality of first transmission plates are combined with each other to have a ring shape, when viewed from the top,
wherein the first waveguide is formed in a ring shape when viewed from the top.
